(19) United States
(12) Patent Application Publication
(10) Pub. No.: US 2025/0100869 A1
(43) Pub. Date: Mar. 27, 2025

(54) PROBE AND METHOD OF FABRICATING ULTRASONIC TRANSDUCER UNIT

(71) Applicant: Qisda Corporation, Taoyuan City (TW)

(72) Inventor: Fu-Sheng Jiang, Taoyuan City (TW)

(73) Assignee: Qisda Corporation, Taoyuan City (TW)

(21) Appl. No.: 18/829,310

(22) Filed: Sep. 10, 2024

(30) Foreign Application Priority Data
Sep. 25, 2023 (TW) 112136559

(51) Int. Cl. B81B 3/00; B81C 1/00; G01N 29/24

(52) U.S. Cl. CPC B81B 3/0021; B81C 1/00182; G01N 29/2406; B81B 2201/0271; B81B 2203/0127; B81B 2203/0315; B81B 2203/04; B81C 2201/0105; B81C 2201/013; B81C 2201/019

(57) ABSTRACT

A probe including a shell, an ultrasonic transducer unit, and at least one circuit board is provided. The ultrasonic transducer unit is disposed in the shell and includes a substrate, a vibrating membrane, and an anti-resonance structure. The vibrating membrane is disposed on the substrate and forms a cavity with the substrate. The anti-resonance structure is disposed on one side of the substrate facing away from the vibrating membrane and includes a hard layer and a glue layer connected to each other. The density of the glue layer is different from the density of the hard layer. The at least one circuit board is electrically coupled to the ultrasonic transducer unit. A method of fabricating the ultrasonic transducer unit is also provided.

### CROSS-REFERENCE TO RELATED APPLICATION

This application claims the priority benefit of Taiwan application serial no. 112136559, filed on Sep. 25, 2023. The entirety of the above-mentioned patent application is hereby incorporated by reference herein and made a part of this specification.

### TECHNICAL FIELD

This disclosure relates to a device and a method of fabricating the same, and in particular to a probe and a method of fabricating an ultrasonic transducer unit.

### DESCRIPTION OF RELATED ART

The ultrasonic transducer is a transducer that realizes the mutual conversion of sound energy and electrical energy within the ultrasonic frequency range. Ultrasonic transducers may be mainly divided into three categories: 1. Transmitter; 2. Receiver; and 3. Transceiver transducer. The transducer used to emit ultrasonic waves is called the transmitter. When the transducer is transmitting, electrical energy is converted into mechanical energy and then converted into sound energy. The transducer used to receive sound waves is called the receiver. When the transducer is receiving, sound energy is converted into mechanical energy and then converted into electrical energy. In some cases, the transducer may be used as both a transmitter and a receiver, and is called the transceiver transducer. The transceiver transducer is the core content and one of the critical technologies of ultrasonic technology and is widely used in fields such as non-destructive testing, medical imaging, ultrasonic microscopes, fingerprint recognition, and the Internet of Things.

To obtain clearer ultrasonic images, the signal-to-noise ratio of the ultrasonic transducer must reach a certain level within the usable spectrum range. However, in the conventional ultrasonic transducer, the substrate easily produces resonance at a specific membrane vibration frequency, which causes a decrease in the signal-to-noise ratio at some frequencies in the membrane vibration spectrum and the inability to produce clear ultrasonic images.

### SUMMARY

This disclosure provides a probe, which has good ultrasonic imaging resolution.

This disclosure provides a method of fabricating an ultrasonic transducer unit, which has good process flexibility.

The probe of this disclosure includes a shell, an ultrasonic transducer unit, and at least one circuit board. The ultrasonic transducer unit is disposed in the shell and includes a substrate, a vibrating membrane, and an anti-resonance structure. The vibrating membrane is disposed on the substrate and forms a cavity with the substrate. The anti-resonance structure is disposed on one side of the substrate facing away from the vibrating membrane and includes a hard layer and a glue layer connected to each other. A density of the glue layer is different from a density of the hard layer. The at least one circuit board is electrically coupled to the ultrasonic transducer unit.

The method of fabricating the ultrasonic transducer unit of this disclosure includes forming a vibrating membrane on one side of a substrate, forming a cavity between the substrate and the vibrating membrane, and forming an anti-resonance structure on other side of the substrate facing away from the vibrating membrane. Forming the anti-resonance structure includes forming a hard layer and a glue layer connected to each other and having different densities.

Based on the above, in the probe of the embodiment of this disclosure, the ultrasonic transducer unit is provided with the anti-resonance structure on one side of the substrate facing away from the vibrating membrane. Through the density of the hard layer being different from the density of the glue layer of the anti-resonance structure, the resonance phenomenon of the substrate can be effectively suppressed, thereby improving the integrity of the vibration spectrum of the vibrating membrane. In other words, the ultrasonic transducer unit of this embodiment has a good signal-to-noise ratio within the vibration frequency range, which helps to improve the resolution of an ultrasonic image generated by the probe.

### BRIEF DESCRIPTION OF THE DRAWINGS

FIG. 1 is a schematic side view of a probe in accordance with the first embodiment of this disclosure.

FIG. 2 is a schematic cross-sectional view of an ultrasonic transducer unit of FIG. 1.

FIG. 3A to FIG. 3C are schematic cross-sectional views of a process of fabricating the ultrasonic transducer unit of FIG. 2.

FIG. 4 is a schematic cross-sectional view of an ultrasonic transducer unit in accordance with the second embodiment of this disclosure.

FIG. 5 is a schematic rear view of the ultrasonic transducer unit of FIG. 4.

FIG. 6A to FIG. 6C are schematic cross-sectional views of a process of fabricating the ultrasonic transducer unit of FIG. 4.

FIG. 7 is a schematic cross-sectional view of an ultrasonic transducer unit in accordance with the third embodiment of this disclosure.

FIG. 8 is a schematic cross-sectional view of an ultrasonic transducer unit in accordance with the fourth embodiment of this disclosure.

FIG. 9 is a schematic cross-sectional view of an ultrasonic transducer unit in accordance with the fifth embodiment of this disclosure.

FIG. 10 is a schematic cross-sectional view of an ultrasonic transducer unit in accordance with the sixth embodiment of this disclosure.

FIG. 11 is a schematic view of a distribution of signal-to-noise ratio versus frequency of an ultrasonic transducer unit in accordance with multiple embodiments and comparative examples of this disclosure.

### DETAILED DESCRIPTION OF DISCLOSED EMBODIMENTS

As used herein, “about”, “approximately”, “essentially”, or “substantially” includes the stated value and an average within an acceptable range of deviations from the particular value as determined by one of ordinary skill in the art, taking into account the measurement in question and the specific amount of error associated with the measurement (i.e., the limitations of the measurement system). For example, “about” may mean within one or more standard deviations of the stated value or, for example, within ±30%, ±20%, ±10%, or ±5%. Furthermore, “about”, “approximately”, “essentially”, or “substantially” used in this article can be used to select a more acceptable deviation range or standard deviation based on measurement properties, cutting properties, or other properties without applying one standard deviation to all properties.

In the drawings, the thicknesses of layers, films, panels, regions, etc., are exaggerated for clarity. It should be understood that when an element such as a layer, a film, a region, or a substrate is referred to as being “on” or “connected to” another element, the element may be directly on or connected to the other element, or an intermediate element may also be present. In contrast, when an element is referred to as being “directly on” or “directly connected to” another element, no intermediate element is present. As used herein, the “connection” may refer to physical and/or electrical connection. Furthermore, the “electrical connection” may include the presence of other elements between the two elements.

Furthermore, relative terms, such as “lower” or “bottom” and “upper” or “top”, may be used herein to describe the relationship of one element to another element as illustrated in the drawings. It will be understood that the relative terms are intended to include different orientations of a device in addition to the orientations depicted in the drawings. For example, if the device in one of the drawings is turned over, elements described as being on the “lower” side of other elements will then be oriented on the “upper” side of the other elements. Therefore, the exemplary term “lower” may include both the orientations of “lower” and “upper”, depending on the particular orientation of the drawing. Similarly, if the device in one of the drawings is turned over, elements described as “below” or “beneath” other elements will then be oriented “above” the other elements. Therefore, the exemplary term “on” or “under” may include both the orientations of above and below.

Reference will now be made in detail to the exemplary embodiments of this disclosure, and examples of the exemplary embodiments are illustrated in the drawings. Whenever possible, the same reference numerals are used in the drawings and descriptions to refer to the same or similar parts.

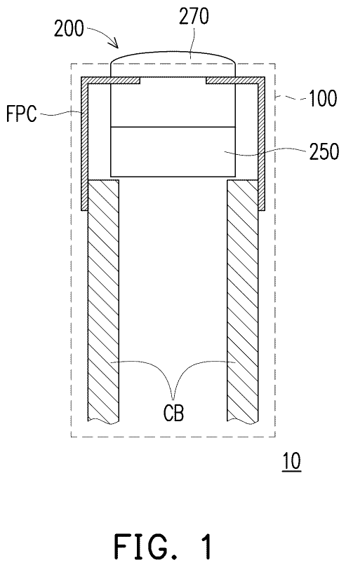

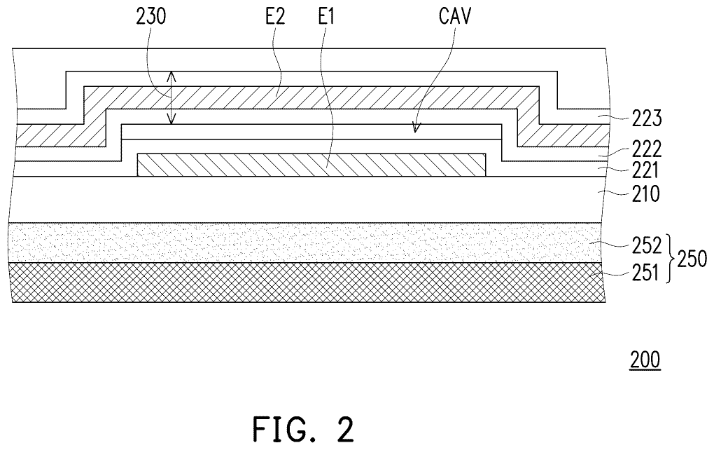

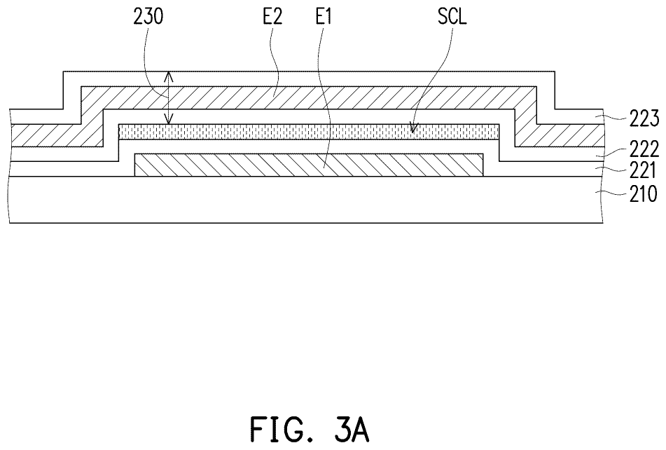

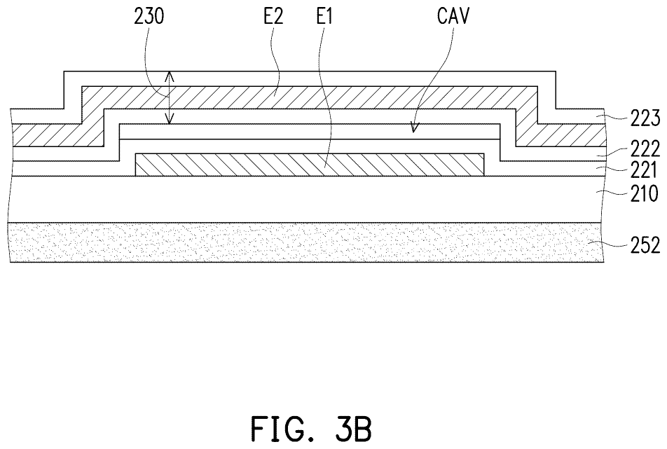

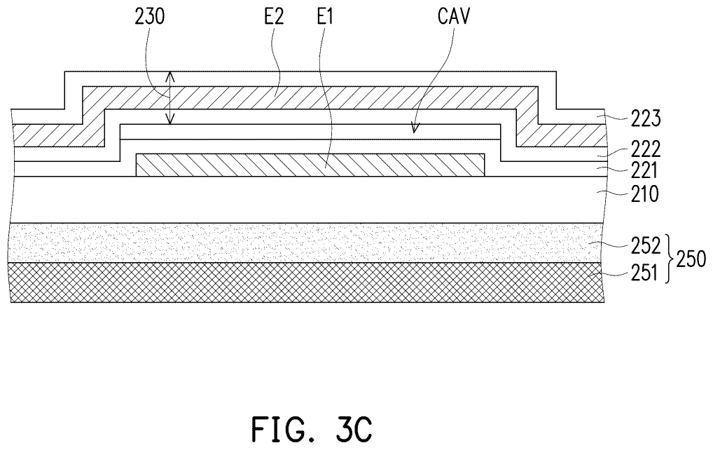

FIG. 1 is a schematic side view of a probe in accordance with the first embodiment of this disclosure. FIG. 2 is a schematic cross-sectional view of an ultrasonic transducer unit of FIG. 1. FIG. 3A to FIG. 3C are schematic cross-sectional views of a process of fabricating the ultrasonic transducer unit of FIG. 2. FIG. 2 omits the illustration of an acoustic lens 270 of FIG. 1.

Please refer to FIG. 1. A probe 10 includes a shell 100, an ultrasonic transducer unit 200, and a circuit board CB. The ultrasonic transducer unit 200 is disposed in the shell 100 and is electrically coupled to the circuit boards CB. In this embodiment, the circuit board CB is, for example, a printed circuit board assembly (PCBA) or a flexible printed circuit (FPC), and the number thereof is, for example, two. The two circuit boards CB may be respectively located on two opposite sides of the ultrasonic transducer unit 200 and is each electrically coupled to the ultrasonic transducer unit 200 via a flexible printed circuit FPC.

However, this disclosure is not limited thereto. In another embodiment, the number of each of the circuit board CB and the flexible printed circuit FPC may be one, and the circuit board CB and the flexible printed circuit FPC are electrically coupled to one side of the ultrasonic transducer unit 200. In another embodiment, the number of the circuit board CB may be two, and the number of the flexible printed circuit FPC may be one, and the two circuit boards CB may be electrically coupled to the ultrasonic transducer unit 200 via the same flexible printed circuit FPC. In another embodiment, the circuit board CB and the flexible printed circuit FPC may also be replaced by an integrated flexible printed circuit.

It should be noted that although only one ultrasonic transducer unit 200 is illustrated for the probe 10 of FIG. 1, this disclosure is not limited thereto. In practical applications, such as an ultrasonic imager, the probe may be provided with multiple ultrasonic transducer units 200 arranged in an array, and the ultrasonic transducer units 200 may respectively correspond to one pixel in an ultrasonic image, but not limited thereto.

The ultrasonic transducer unit 200 includes a substrate 210 and a vibrating membrane 230 disposed on the substrate 210. The vibrating membrane 230 and the substrate 210 may form a cavity CAV. For instance, in this embodiment, the ultrasonic transducer unit 200 further includes a first electrode E1 and a second electrode E2 disposed on two opposite sides of the cavity CAV. The first electrode E1 is disposed on the substrate 210 at a position that overlaps the cavity CAV and is covered by an insulation layer 221. The two opposite surfaces of the second electrode E2 are both covered with an insulation layer 222 and an insulation layer 223.

In particular, parts of the second electrode E2, the insulation layer 222, and the insulation layer 223 above the cavity CAV constitute the vibrating membrane 230 of the ultrasonic transducer unit 200. More specifically, in this embodiment, the ultrasonic transducer unit 200 is, for example, a capacitive micromachined ultrasonic transducer (CMUT). However, this disclosure is not limited thereto. In another embodiment, the ultrasonic transducer unit may also be a piezoelectric micromachined ultrasonic transducer (PMUT). In the piezoelectric micromachined ultrasonic transducer, the first electrode E1 and the second electrode E2 are both located above the cavity CAV and form a part of the vibrating membrane.

For instance, the first electrode E1 may be electrically coupled to a reference power supply (such as ground). The second electrode E2 on the vibrating membrane 230 may be electrically coupled to a direct current power supply, and uses the output voltage of the direct current power supply as a reference bias voltage. In addition, the second electrode E2 is also electrically coupled to an alternating current power supply. After receiving a direct current bias voltage from the direct current power supply and an alternating current voltage from the alternating current power supply, the second electrode E2 drives the vibrating membrane 230 to vibrate to produce ultrasonic signals.

To suppress the resonance phenomenon of the substrate 210, such as a ringing effect produced by the substrate 210, the ultrasonic transducer unit 200 further includes an anti-resonance structure 250 disposed on one side of the substrate 210 facing away from the vibrating membrane 230. The anti-resonance structure 250 includes a hard layer 251 and a glue layer 252 having different densities. In this embodiment, the glue layer 252 is connected between the substrate 210 and the hard layer 251. More specifically, the hard layer 251 is attached to the surface of the substrate 210 on the side facing away from the vibrating membrane 230 via the glue layer 252. In this embodiment, the hard layer 251 is, for example, a glass plate, and the glue layer 252 is, for example, an epoxy layer, but not limited thereto.

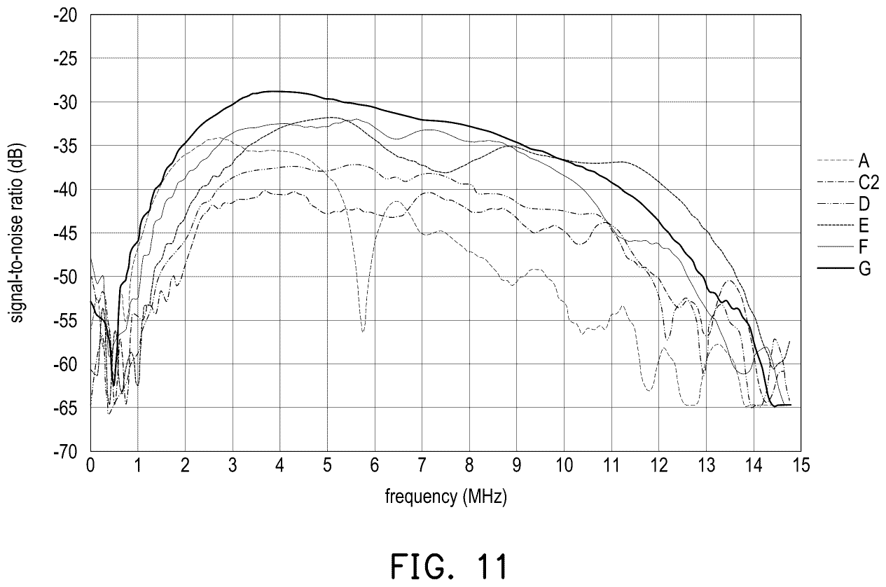

Curve A in FIG. 11 illustrates a distribution of signal-to-noise ratio (SNR) versus frequency of an ultrasonic transducer unit of the comparative example. Curve C2 in FIG. 11 illustrates a distribution of signal-to-noise ratio versus frequency of the ultrasonic transducer unit 200 of this embodiment. As seen in FIG. 11, since the ultrasonic transducer unit of the comparative example is not provided with the anti-resonance structure 250 of this embodiment, the signal-to-noise ratio near the frequency of 6 MHz and multiple frequencies thereof is significantly reduced due to the resonance phenomenon of the substrate, resulting in a decrease in imaging resolution.

In other words, the setting of the anti-resonance structure 250 can ensure the integrity of the signal-to-noise ratio of the ultrasonic transducer unit 200 of this embodiment in the vibration spectrum. Thus, compared with the ultrasonic transducer unit of the comparative example, the resolving power of the ultrasonic image of the probe 10 can be significantly improved. In other words, the resolution of the ultrasonic image generated by the probe 10 can be significantly improved.

Furthermore, in this embodiment, the ultrasonic transducer unit 200 may also optionally include an acoustic lens 270. The acoustic lens 270 is disposed on an ultrasonic emission side of the vibrating membrane 230 facing away from the substrate 210 (i.e., above the vibrating membrane 230 in FIG. 2) and overlaps the vibrating membrane 230 and the cavity CAV. The acoustic lens 270 is suitable for focusing ultrasonic waves generated by the vibrating membrane 230 in space and transmitting the ultrasonic waves to a target object, or transmitting the ultrasonic waves reflected via the target object to the vibrating membrane 230, which can enhance the signal of the ultrasonic image.

The following is an exemplary explanation of the process of fabricating the ultrasonic transducer unit 200. Please refer to FIG. 3A. First, a vibrating membrane 230 is formed on one side of the substrate 210. The substrate 210 is, for example, a glass substrate or a wafer substrate, but not limited thereto.

For instance, forming the vibrating membrane 230 may include sequentially forming a sacrificial layer SCL, the insulation layer 222, the second electrode E2, and the insulation layer 223 on the insulation layer 221, wherein the sacrificial layer SCL overlaps the first electrode E1 on the substrate 210.

The insulation layer 221, the insulation layer 222, and the insulation layer 223 are, for example, passivation layers and may be silicon oxide layers, silicon nitride layers, silicon oxynitride layers, aluminum oxide layers, or dielectric layers formed of other suitable dielectric materials, but not limited thereto. The material of the sacrificial layer SCL includes, for example, aluminum, copper, silver, silicon oxide, etc. Next, the sacrificial layer SCL is etched to form the cavity CAV between the vibrating membrane 230 and the insulation layer 221 (or the substrate 210), as shown in FIG. 3B.

Please refer to FIG. 3C. The method of fabricating the ultrasonic transducer unit 200 also includes forming the anti-resonance structure 250 on the other side of the substrate 210 facing away from the vibrating membrane 230. Forming the anti-resonance structure 250 includes forming the hard layer 251 and the glue layer 252 connected to each other and having different densities. For instance, in this embodiment, the glue layer 252 is formed before the hard layer 251 is formed, but not limited thereto.

In this embodiment, the method of fabricating the ultrasonic transducer unit 200 may also optionally include forming the acoustic lens 270 on the side of the vibrating membrane 230 facing away from the substrate 210. The material of the acoustic lens 270 includes, for example, silicone, rubber, or polybutadiene glue.

At this point, the production of the ultrasonic transducer unit 200 of this embodiment is completed. As shown in FIG. 2, the ultrasonic transducer unit 200 includes the substrate 210, the vibrating membrane 230, and the anti-resonance structure 250. The vibrating membrane 230 is disposed on the substrate 210 and forms the cavity CAV with the substrate 210. The anti-resonance structure 250 is disposed on the side of the substrate 210 facing away from the vibrating membrane 230 and includes the hard layer 251 and the glue layer 252 connected to each other. Since the density of the hard layer 251 is different from the density of the glue layer 252 of the anti-resonance structure 250, the resonance phenomenon of the substrate 210 can be effectively suppressed, thereby improving the integrity of the vibration spectrum of the vibrating membrane 230.

Other embodiments are enumerated below to describe this disclosure in detail, wherein the same components are marked with the same numerals, and explanations of the same technical content are omitted. Please refer to the previous embodiments for the omitted parts, which will not be described again.

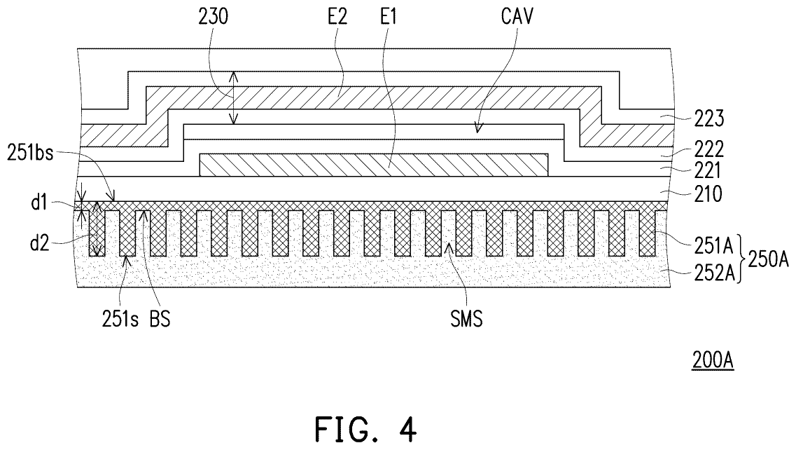

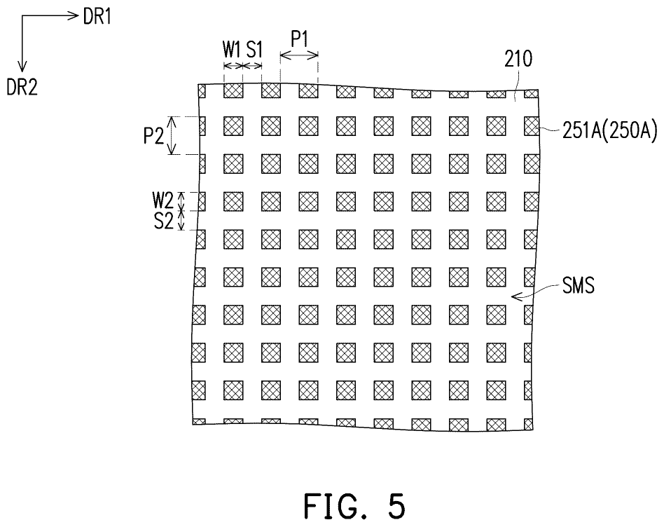

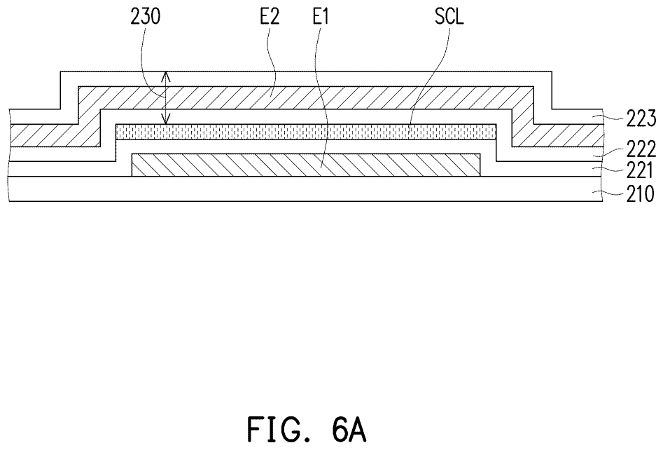

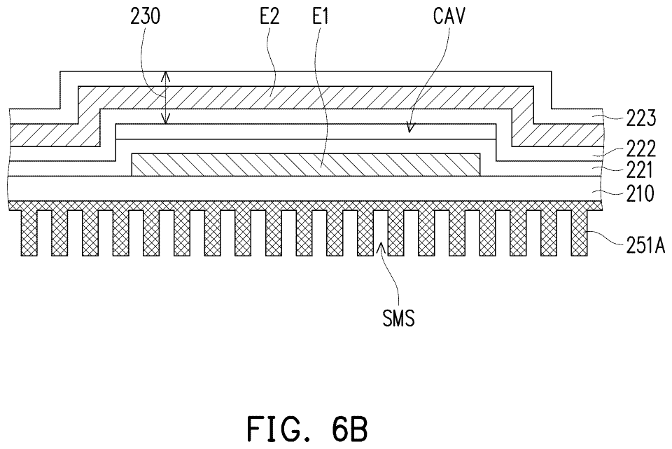

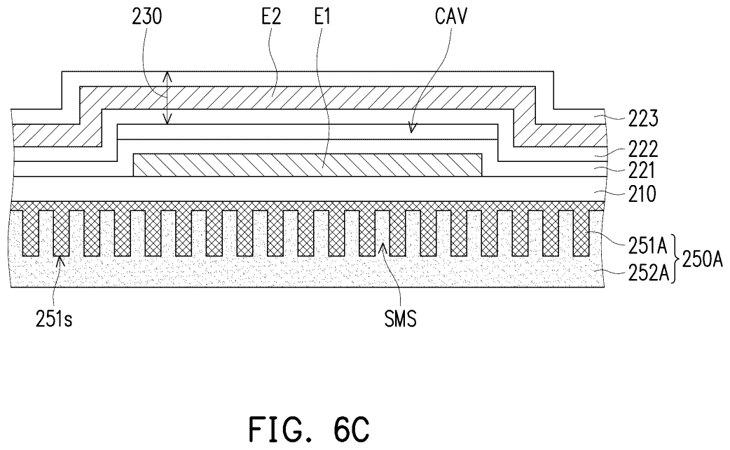

FIG. 4 is a schematic cross-sectional view of an ultrasonic transducer unit in accordance with the second embodiment of this disclosure. FIG. 5 is a schematic rear view of the ultrasonic transducer unit of FIG. 4. FIG. 6A to FIG. 6C are schematic cross-sectional views of a process of fabricating the ultrasonic transducer unit of FIG. 4.

Please refer to FIG. 4 and FIG. 5. The difference between an ultrasonic transducer unit 200A of this embodiment and the ultrasonic transducer unit 200 of FIG. 2 is that the structure and the composition of the anti-resonance structure are different. For instance, in this embodiment, a hard layer 251A of an anti-resonance structure 250A may include multiple surface microstructures SMS disposed on one side of the hard layer 251A facing away from the substrate 210. Of particular interest is that, unlike the glue layer 252 of FIG. 2, which is disposed between the hard layer 251 and the substrate 210, a glue layer 252A of this embodiment is disposed on one side of the surface microstructures SMS facing away from the substrate 210 and fills in the surface microstructures SMS on the hard layer 251A.

In this embodiment, the surface microstructures SMS, for example, are multiple micro-slots and are arranged at equal spacings along at least one direction. For instance, in this embodiment, the surface microstructures SMS may be arranged at intervals with a first pitch P1 along a first direction DR1 and arranged at intervals with a second pitch P2 along a second direction DR2 (as shown in FIG. 5). The first direction DR1 may be optionally perpendicular to the second direction DR2, but not limited thereto.

The hard layer 251A also includes multiple protruding structures defining multiple micro-slots. Each protruding structure has a first width W1 and a second width W2 along the first direction DR1 and the second direction DR2, respectively. Preferably, the percentage value of the first width W1 to the first pitch P1 is in the range of 30% to 70%, and the percentage value of the second width W2 to the second pitch P2 is in the range of 30% to 70%.

From another point of view, a part of the micro-slots (i.e., surface microstructures SMS) arranged along the first direction DR1 and between two adjacent protruding structures has a first spacing S1 along the first direction DR1, and another part of the micro-slots arranged along the second direction DR2 and between two adjacent protruding structures has a second spacing S2 along the second direction DR2. The percentage value of the first spacing S1 to the first pitch P1 is in the range of 30% to 70%, and the percentage value of the second spacing S2 to the second pitch P2 is in the range of 30% to 70%. For instance, the micro-slots of this embodiment may be formed by using a knife tool to cut, so the percentage value of the knife width to the cutting pitch is also in the range of 30% to 70%.

Of particular interest is that, in this embodiment, the surface microstructures SMS are connected to each other. More specifically, the orthographic projection of an area occupied by the surface microstructures SMS on the substrate 210 is in a grid shape.

On the other hand, the surface microstructure SMS (i.e., micro-slot) may be recessed from a surface 251s of the hard layer 251A facing away from the substrate 210 and has a slot bottom surface BS. There is a first distance d1 between the slot bottom surface BS and a back surface 251bs of the hard layer 251A facing away from the surface 251s. There is a second distance d2 between the surface 251s and the back surface 251bs of the hard layer 251A. Preferably, the percentage value of the first distance d1 to the second distance d2 is in the range of 5% to 95%.

The following is an exemplary explanation of the process of fabricating the ultrasonic transducer unit 200A. Please refer to FIG. 6A. First, the vibrating membrane 230 is formed on one side of the substrate 210. The substrate 210 is, for example, a glass substrate or a wafer substrate, but not limited thereto.

For instance, forming the vibrating membrane 230 may include sequentially forming the sacrificial layer SCL, the insulation layer 222, the second electrode E2, and the insulation layer 223 on the insulation layer 221, wherein the sacrificial layer SCL overlaps the first electrode E1 on the substrate 210.

The insulation layer 221, the insulation layer 222, and the insulation layer 223 are, for example, passivation layers and may be silicon oxide layers, silicon nitride layers, silicon oxynitride layers, or dielectric layers formed of other suitable dielectric materials, but not limited thereto. The material of the sacrificial layer SCL includes, for example, aluminum, copper, silver, silicon oxide, etc. Next, the sacrificial layer SCL is etched to form the cavity CAV between the vibrating membrane 230 and the insulation layer 221 (or the substrate 210), as shown in FIG. 6B. The method of fabricating the ultrasonic transducer unit 200A also includes forming the anti-resonance structure 250A on the other side of the substrate 210 facing away from the vibrating membrane 230. Forming the anti-resonance structure 250A includes forming the hard layer 251A and the glue layer 252A connected to each other and having different densities. For instance, in this embodiment, the hard layer 251A is formed before the glue layer 252A is formed, but not limited thereto.

Particularly, in this embodiment, forming the hard layer 251A includes, for example, using a knife tool (not shown) to cut the surface 251s of the hard layer 251A facing away from the substrate 210 along the first direction DR1 and the second direction DR2 of FIG. 5 to form the micro-slots (i.e., the surface microstructures SMS) recessed from the surface 251s. After forming the surface microstructures SMS, the glue layer 252A is formed on the side of the surface 251s of the hard layer 251A, as shown in FIG. 6C. The glue layer 252A is, for example, a silver glue layer or a mixture of epoxy and metal powder (such as tungsten or alumina), glass powder, ceramic powder, silicon powder, etc.

The method of fabricating the ultrasonic transducer unit 200A also optionally includes forming the acoustic lens 270 on the side of the vibrating membrane 230 facing away from the substrate 210. The material of the acoustic lens 270 includes, for example, silicone, rubber, polybutadiene glue, etc.

At this point, the production of the ultrasonic transducer unit 200A of this embodiment is completed. As shown in FIG. 4, the ultrasonic transducer unit 200A includes the substrate 210, the vibrating membrane 230, and the anti-resonance structure 250A. The vibrating membrane 230 is disposed on the substrate 210 and forms the cavity CAV with the substrate 210. The anti-resonance structure 250A is disposed on the side of the substrate 210 facing away from the vibrating membrane 230 and includes the hard layer 251A and the glue layer 252A connected to each other. In addition to the density of the hard layer 251A of the anti-resonance structure 250A being different from the density of the glue layer 252A, the hard layer 251A is also provided with the surface microstructures SMS on the surface 251s on the side facing away from the substrate 210. Thus, compared with the ultrasonic transducer unit 200 of FIG. 2, in addition to suppressing the resonance phenomenon of the substrate 210, the signal-to-noise ratio of the vibration spectrum of the ultrasonic transducer unit 200A of this embodiment can also be further improved (as shown by curve C2 and curve D of FIG. 11).

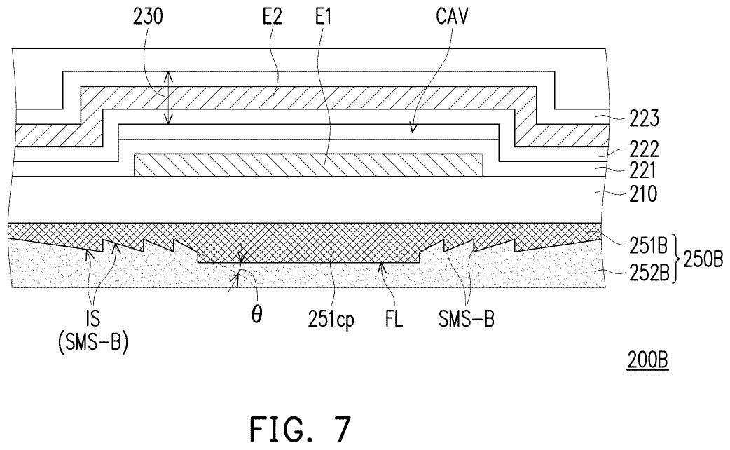

FIG. 7 is a schematic cross-sectional view of an ultrasonic transducer unit in accordance with the third embodiment of this disclosure. Please refer to FIG. 7. The difference between an ultrasonic transducer unit 200B of this embodiment and the ultrasonic transducer unit 200A of FIG. 4 is that the arrangement and the configuration of the surface microstructures are different. For instance, in this embodiment, a hard layer 251B of an anti-resonance structure 250B has a center part 251cp, and multiple surface microstructures SMS-B are disposed on two opposite sides of the center part 251cp.

Of particular interest is that the surface microstructures SMS-B may be multiple wedge-shaped structures, and each has an inclined surface IS facing away from the center part 251cp. An included angle θ between the inclined surface IS of each wedge-shaped structure and a plane FL of the center part 251cp facing away from the substrate 210 decreases as the distance from the center part 251cp increases. More specifically, in this embodiment, the wedge-shaped structures may form a Fresnel lens with defocusing ability. In this embodiment, a glue layer 252B that fills in the wedge-shaped structures is, for example, a silver glue layer or a mixture of epoxy and metal powder (such as tungsten or alumina), glass powder, ceramic powder, silicon powder, etc.

It may be seen from curve E and curve C2 of FIG. 11 that, compared with the ultrasonic transducer unit 200A of FIG. 4, the signal-to-noise ratio of the ultrasonic transducer unit 200B of this embodiment in the vibration spectrum is further improved.

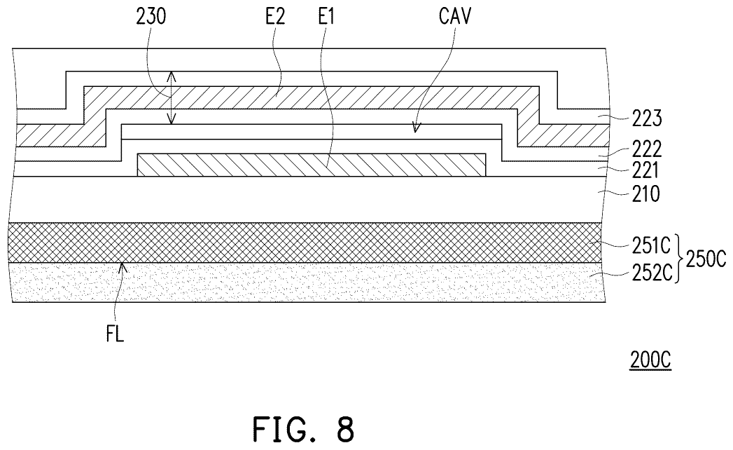

FIG. 8 is a schematic cross-sectional view of an ultrasonic transducer unit in accordance with the fourth embodiment of this disclosure. Please refer to FIG. 8. The difference between an ultrasonic transducer unit 200C of this embodiment and the ultrasonic transducer unit 200 of FIG. 2 is that the composition and the stacking manner of the anti-resonance structure are different.

For instance, in this embodiment, a hard layer 251C of an anti-resonance structure 250C has the plane FL facing away from the substrate 210, and a glue layer 252C is connected to the plane FL of the hard layer 251C. In this embodiment, the hard layer 251C is, for example, a glass layer. The material of the glue layer 252C includes, for example, a mixture of epoxy and tungsten.

It may be seen from curve F and curve C2 of FIG. 11 that, compared with the ultrasonic transducer unit 200 of FIG. 2, the signal-to-noise ratio of the ultrasonic transducer unit 200C of this embodiment in the vibration spectrum is further improved.

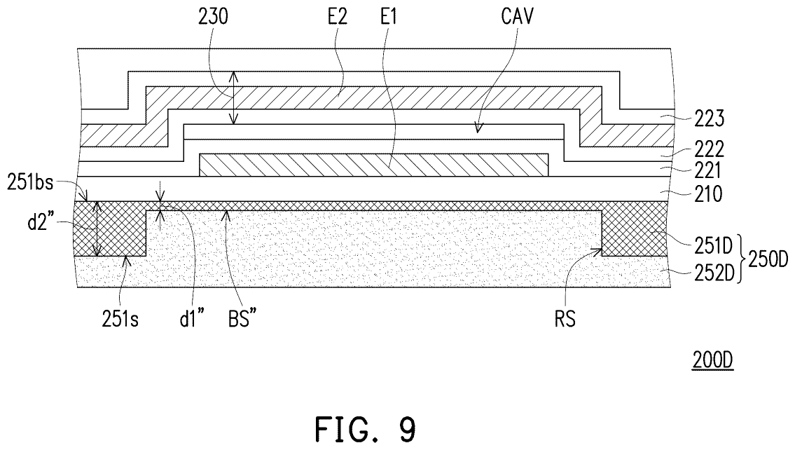

FIG. 9 is a schematic cross-sectional view of an ultrasonic transducer unit in accordance with the fifth embodiment of this disclosure. Please refer to FIG. 9. The difference between an ultrasonic transducer unit 200D of this embodiment and the ultrasonic transducer unit 200C of FIG. 8 is that the configuration of the hard layer is different. For instance, in this embodiment, a hard layer 251D of an anti-resonance structure 250D is also provided with a notch RS recessed from the surface 251s on the surface 251s facing away from the substrate 210, and a glue layer 252D covers the surface 251s of the hard layer 251D and fills in the notch RS.

Of particular interest is that, the orthographic projection of the cavity CAV on the substrate 210 is within the orthographic projection of the notch RS of the hard layer 251D on the substrate 210. That is, the cavity CAV completely overlaps within the setting range of the notch RS. From another point of view, by the setting of the notch RS, the thickness of a part of the hard layer 251D that overlaps the cavity CAV (or the vibrating membrane 230) can be significantly smaller than the other part that does not overlap the cavity CAV. Since the hard layer 251D has a thicker thickness in the part that does not overlap the cavity CAV, the transporting requirements of the ultrasonic transducer unit 200D during the process of fabricating can be satisfied.

For instance, the hard layer 251D has a notch bottom surface BS″ defining the notch RS. There is a first distance d1″ between the notch bottom surface BS″ and the back surface 251bs of the hard layer 251D. There is a second distance d2″ between the surface 251s and the back surface 251bs of the hard layer 251D. Preferably, the percentage value of the first distance d1″ to the second distance d2″ is in the range of 5% to 95%.

As seen from curve G and curve F of FIG. 11, compared with the ultrasonic transducer unit 200C of FIG. 8, the signal-to-noise ratio of the ultrasonic transducer unit 200D of this embodiment in the vibration spectrum is further improved.

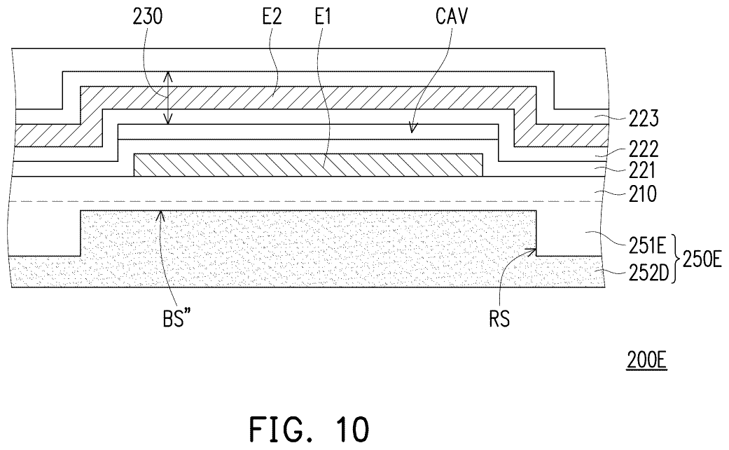

FIG. 10 is a schematic cross-sectional view of an ultrasonic transducer unit in accordance with the sixth embodiment of this disclosure. Please refer to FIG. 10. The difference between an ultrasonic transducer unit 200E of this embodiment and the ultrasonic transducer unit 200D of FIG. 9 is that the material of the hard layer is different.

For instance, in the ultrasonic transducer unit 200D of FIG. 9, the substrate 210 is, for example, a wafer substrate, and the material of the hard layer 251D is, for example, glass. However, in the ultrasonic transducer unit 200E of this embodiment, the substrate 210 and a hard layer 251E may be integrated and formed by, for example, the same glass plate, wherein the notch RS is formed on the surface on the side of the glass plate facing away from the vibrating membrane 230.

Similarly, in other modified embodiments of FIG. 4, FIG. 7, and FIG. 8, each of the hard layer 251A of FIG. 4, the hard layer 251B of FIG. 7, and the hard layer 251C of FIG. 8 and the substrate 210 may also be integrated and formed by, for example, the same glass plate or wafer, but not limited thereto.

It should be noted that the ultrasonic transducer unit 200A of FIG. 4, the ultrasonic transducer unit 200B of FIG. 7, the ultrasonic transducer unit 200C of FIG. 8, the ultrasonic transducer unit 200D of FIG. 9 and the ultrasonic transducer unit 200E of FIG. 10 may all be used to replace the ultrasonic transducer unit 200 in the probe 10 of FIG. 1.

To sum up, in the probe of the embodiment of this disclosure, the ultrasonic transducer unit is provided with the anti-resonance structure on the side of the substrate facing away from the vibrating membrane. Through the density of the hard layer being different from the density of the glue layer of the anti-resonance structure, the resonance phenomenon of the substrate can be effectively suppressed, thereby improving the integrity of the vibration spectrum of the vibrating membrane. In other words, the ultrasonic transducer unit of this embodiment has a good signal-to-noise ratio within the vibration frequency range, which helps to improve the resolution of the ultrasonic image generated by the probe.

What is claimed is:

1. A probe, comprising:
a shell;
an ultrasonic transducer unit, disposed in the shell and comprising:
a substrate;
a vibrating membrane, disposed on the substrate and forming a cavity with the substrate; and
an anti-resonance structure, disposed on one side of the substrate facing away from the vibrating membrane and comprising:
a hard layer; and
a glue layer, connected to the hard layer, wherein a density of the glue layer is different from a density of the hard layer; and
at least one circuit board, electrically coupled to the ultrasonic transducer unit.

2. The probe according to claim 1, wherein the hard layer is a glass plate, the glue layer is an epoxy layer, and the epoxy layer connects the substrate and the glass plate.

3. The probe according to claim 1, wherein the hard layer comprises a plurality of surface microstructures disposed on one side of the hard layer facing away from the substrate, and the glue layer is disposed on one side of the plurality of surface microstructures facing away from the substrate and fills in the plurality of surface microstructures.

4. The probe according to claim 3, wherein the plurality of surface microstructures are arranged at equal spacings along at least one direction.

5. The probe according to claim 4, wherein an orthographic projection of an area occupied by the plurality of surface microstructures on the substrate is in a grid shape.

6. The probe according to claim 4, wherein the plurality of surface microstructures are a plurality of micro-slots, the plurality of micro-slots are recessed from a surface of the hard layer facing away from the substrate and each has a slot bottom surface, there is a first distance between the surface of the hard layer and the slot bottom surface, there is a second distance between the surface of the hard layer and a surface of the substrate facing the vibrating membrane, and a percentage value of the first distance to the second distance is in a range of 5% to 95%.

7. The probe according to claim 3, wherein the hard layer further comprises a center part, the plurality of surface microstructures are disposed on two opposite sides of the center part and are a plurality of wedge-shaped structures, and the plurality of wedge-shaped structures each has an inclined surface facing away from the center part.

8. The probe according to claim 7, wherein the center part has a plane facing away from the substrate, and an included angle between the inclined surface and the plane of each of the plurality of wedge-shaped structures decreases as a distance from the center part increases.

9. The probe according to claim 1, wherein the ultrasonic transducer unit further comprises:
an acoustic lens, wherein the vibrating membrane has an ultrasonic emission side facing away from the substrate, and the acoustic lens is disposed on the ultrasonic emission side of the vibrating membrane and overlaps the vibrating membrane.

10. The probe according to claim 1, wherein the hard layer has a plane facing away from the substrate, the glue layer is connected to the plane of the hard layer, and a material of the glue layer comprises a mixture of epoxy and tungsten.

11. The probe according to claim 1, wherein the hard layer has a surface facing away from the substrate and a notch recessed from the surface, and an orthographic projection of the cavity on the substrate is within an orthogonal projection of the notch on the substrate.

12. The probe according to claim 11, wherein the hard layer also has a notch bottom surface defining the notch, there is a first distance between the notch bottom surface and the surface, there is a second distance between the surface of the hard layer and a surface of the substrate facing the vibrating membrane, and a percentage value of the first distance to the second distance is in a range of 5% to 95%.

13. The probe according to claim 11, wherein the glue layer connects the surface of the hard layer and fills in the notch, and a material of the glue layer comprises a silver glue layer or a mixture of epoxy and metal powder, glass powder, ceramic powder, or silicon powder.

14. The probe according to claim 1, wherein the hard layer and the substrate are integrated.

15. A method of fabricating an ultrasonic transducer unit, comprising:
forming a vibrating membrane on one side of a substrate;
forming a cavity between the substrate and the vibrating membrane;
forming an anti-resonance structure on other side of the substrate facing away from the vibrating membrane, wherein forming the anti-resonance structure comprises forming a hard layer and a glue layer connected to each other and having different densities.

16. The method of fabricating the ultrasonic transducer unit according to claim 15, wherein the glue layer is formed before the hard layer is formed.

17. The method of fabricating the ultrasonic transducer unit according to claim 15, wherein the hard layer is formed before the glue layer is formed.

18. The method of fabricating the ultrasonic transducer unit according to claim 15, wherein forming the hard layer comprises forming a plurality of surface microstructures on one side facing away from the substrate.

19. The method of fabricating the ultrasonic transducer unit according to claim 15, further comprising:
forming an acoustic lens on one side of the vibrating membrane facing away from the substrate.
